(19) United States
(12) Patent Application Publication
(10) Pub. No.: US 2024/0105723 A1
(43) Pub. Date: Mar. 28, 2024

(54) TRANSISTOR STRUCTURE

(71) Applicant: Invention And Collaboration Laboratory Pte. Ltd., Singapore (SG)

(72) Inventors: Chao-Chun LU, Hsinchu (TW); Li-Ping HUANG, Hsinchu (TW)

(73) Assignee: Invention And Collaboration Laboratory Pte. Ltd., Singapore (SG)

(21) Appl. No.: 18/371,125

(22) Filed: Sep. 21, 2023

Related U.S. Application Data
(60) Provisional application No. 63/409,243, filed on Sep. 23, 2022.

(51) Int. Cl. H01L 27/092; H01L 29/08; H01L 29/10; H01L 29/417; H01L 29/78

(52) U.S. Cl. CPC H01L 27/0921; H01L 29/0865; H01L 29/0882; H01L 29/1083; H01L 29/41766; H01L 29/7836

(57) ABSTRACT

A semiconductor substrate with an original semiconductor surface (OSS); a first gate region; a first concave formed in the semiconductor substrate and below the original semiconductor surface; a curved or depressed shape opening formed along the vertical direction of a sidewall of the semiconductor substrate in the first concave; and a first conductive region formed in the first concave and including a first doping region and a second doping region. Wherein the first doping region is formed based on the curved or depressed shape opening along the vertical direction of the sidewall of the semiconductor substrate.

This application claims the benefit of U.S. provisional applications Ser. No. 63/409,243 filed Sep. 23, 2022, the subject matter of which is incorporated herein by reference.

### BACKGROUND OF THE DISCLOSURE

### Field of the Disclosure

The present invention relates to a new transistor and/or a new Complementary MOSFET (CMOS) structure, and particularly to a new planar transistor and/or a new planar Complementary MOSFET (CMOS) structure, for example utilized in a peripheral circuit or sense amplifiers of DRAM, that can reduce current leakage, reduce short channel effect, and prevent latch-up.

### Description of the Related Art

Although advanced technology nodes (such as 3-7 nm) are frequently used in high performance computing applications (such as, Artificial Intelligence (AI), CPU, GPU, etc.), the mature technology nodes (such as 20˜30 nm) are still popular in many IC applications, such as power management IC, MCU, or DRAM chip. Using DRAM as an example, nowadays most customized DRAMs are still manufactured by the mature technology nodes (such as, 12-30 nm), and all transistors in DRAM chip 17 (as shown in FIG. 1A), including those in peripheral circuit 171 (at least including data/address I/O circuits, address decoders, command logic, and refresh circuits, etc.) and those in array core circuit 172 (including storage memory arrays, sense amplifiers, etc.) are still planar transistors.

FIG. 1B shows a cross-sectional view of a state-of-the-art planar Complementary Metal-Oxide-Semiconductor Field-Effect Transistors (CMOSFETs) 10 which are most widely used in the peripheral circuit of DRAM chip and in sense amplifiers of array core circuit of DRAM chip. The CMOSFETs 10 includes a planar NMOS transistor 11 and a planar PMOS transistor 12, wherein a Shallow Trench Isolation (STI) region 13 is positioned between the NMOS transistor 11 and the PMOS transistor 12. The gate structure 14 of the NMOS transistor 11 or the PMOS transistor 12 using some conductive material (like metal, polysilicon or silicide, etc.) over an insulator (such as oxide, oxide/nitride or some high-k dielectric, etc.) is formed on top of the CMOS whose sidewalls are isolated from those of other transistors by using insulation materials (e.g. oxide or oxide/nitride or other dielectrics). For the planar NMOS transistor 11 there are source and drain regions which are formed by an Ion-implantation plus Thermal Annealing technique to implant n-type dopants into a p-type substrate (or a p-well) which thus results in two separated n+/p junction areas. For the planar PMOS transistor 12 both source and drain regions are formed by ion-implanting p-type dopants into an n-well which thus results in two p+/n junction areas. Furthermore, to lessen impact ionization and hot carrier injection prior to highly doped n+/p or p+/n junction, it is common to form a lightly doped-drain (LDD) region 15 under the gate structure.

On one hand, during the previously mentioned thermal annealing process, the implanted n-type or p-type dopants in the CMOSFETs 10 will unavoidably diffuse into different directions and enlarge the area of the source and drain regions. Moreover, another thermal annealing process will happen during the formation of capacitors over the access transistors in the array core circuit of DRAM chip to reduce the connecting resistance between the capacitor and the access transistor. Such second thermal annealing process again causes the diffusion of n-type or p-type dopants and increases the area of the source and drain regions. The larger the area of the source and drain regions due to the thermal annealing processes, the shorter of the effective channel length (Leff shown in FIG. 1B) between the source and drain regions, and such reduced effective channel length Leff will incur Short Channel Effects (SCE). Therefore, to reduce the impact of SCE, it is common to reserve longer gate length to accommodate the diffusion of n-type or p-type dopants due to thermal annealing. Using technology node (λ) of 25 nm as an example, the reserved gate length would be around 100 nm, almost four times of the technology node λ.

On the other hand, since the NMOS transistor 11 and the PMOS transistor 12 are located respectively inside some adjacent regions of p-substrate and n-well which have been formed next to each other within a close neighborhood, a parasitic junction structure called n+/p/n/p+ (the path marked by dash line in FIG. 1B is called as n+/p/n/p+ Latch-up path) parasitic bipolar device is formed with its contour starting from the n+ region of the NMOS transistor 11 to the p-well to the neighboring n-well and further up to the p+ region of the PMOS transistor 12.

Once there are significant noises occurred on either n+/p junctions or p+/n junctions, an extraordinarily large current may flow through this n+/p/n/p+ junction abnormally which can possibly shut down some operations of CMOS circuits and to cause malfunction of the entire chip. Such an abnormal phenomenon called Latch-up is detrimental for CMOS operations and must be avoided. One way to increase the immunity to Latch-up which is certainly a weakness for CMOS is to increase the distance from n+ region to the p+ region (labeled as Latch-up Distance in FIG. 1B) and both n+ and p+ regions must be designed to be isolated by some vertically oriented oxide (or other suitable insulator materials) as isolation regions which is usually the STI (Shallow Trench Isolation) region 13. Using technology node (λ) of 25 nm as an example, the reserved Latch-up Distance would be around 500 nm, almost 20 times of the technology node λ. More serious efforts to avoid Latch-up must design a guard-band structure which further increases the distance between n+ regions and p+ regions and/or must add extra n+ regions or p+ regions to collect abnormal charges from noise sources. These isolation schemes always increase extra planar areas to sacrifice the die size of CMOS circuits.

Other problems are introduced or getting worse in current DRAM design with planar transistors or CMOSFETs:
(1) All junction leakages resulted by junction formation processes such as forming LDD (Lightly Doped Drain) structure into the substrate/well regions, n+ Source/Drain structures into p-substrate and p+ Source/Drain structures into n-well are getting worse to control since leakage currents occur through both perimeter and bottom areas where extra damages like vacant traps for holes and electrons are harder to be repaired due to lattice imperfections which have been created by ion-implantation.
(2) In addition, since the ion-implantation to form the LDD structure (or the n+/p junction or the p+/n junction) works like bombardments in order to insert ions from the top of a silicon surface straight down to the substrate, it is hard to create uniform material interfaces with lower defects from the Source and Drain regions to the channel and the substrate-body regions since the dopant concentrations are non-uniformly distributed vertically from the top surface with higher doping concentrations down to the junction regions with lower doping concentrations.
(3) It's getting harder to align the LDD junction edge to the edge of gate structure of the transistor in a perfect position by only using the conventional self-alignment method of using gate, spacer and ion-implantation formation. In addition, the Thermal Annealing process for removing the ion-implantation damages must count on high temperature processing techniques such as Rapid Thermal Annealing method by using various energy sources or other thermal processes. One problem thus created is that a Gate-induced Drain Leakage (GIDL) current. As shown in FIG. 1C (cited from: A. Sen and J. Das, “MOSFET GIDL Current Variation with Impurity Doping Concentration—A Novel Theoretical Approach” IEEE ELECTRON DEVICE LETTERS, VOL. 38, NO. 5, MAY 2017), the MOSFET structure with a thin oxide which close to the Gate and Drain/Source region exists parasitic Metal-Gated-Diode, and the GIDL issued is induced due to the parasitic Metal-Gated-Diode formed in the Gate-to-Source/Drain regions and hard to be controlled regardless the fact that it should be minimized to reduce leakage currents; the other problem as created is that the effective channel length is difficult to be controlled and so the SCE is hard to be minimized.
(4) Since the vertical length of STI structures is harder to be made deeper while the planar width of the device isolation must be scaled down (otherwise a worse depth-to-opening aspect ratio were created for integrated processes of making etching, filling and planarization), the proportional ratio of the planar isolation distance between the n+ and p+ regions of the neighbor transistors which is reserved for preventing Latch-up to the shrunken λ cannot be reduced but increased so as to hurt the die area reduction when scaling down CMOS devices.

### SUMMARY OF THE DISCLOSURE

This invention discloses several new concepts of realizing a novel transistor and CMOSFET structure, especially used in the peripheral circuit of DRAM chip and in sense amplifiers of array core circuit of DRAM chip, which greatly improves or even solved most of the problems as stated above, such as minimizing current leakages, increasing channel-conduction performance and control, optimizing functions of source and drain regions such as making better their conductance to metal interconnections and their closest physical intact to the channel region with a seamless orderly crystalline Lattice matchup, increasing higher immunity of CMOS circuits against Latch-up and minimizing the planar area used for layout isolations between NMOS and PMOS in order to avoid Latch-Up.

One object of the present disclosure is to provide a transistor structure, wherein the transistor structure includes a semiconductor substrate with an original semiconductor surface (OSS); a first gate region; a first concave formed in the semiconductor substrate and below the original semiconductor surface; a curved or depressed shape opening formed along the vertical direction of a sidewall of the semiconductor substrate in the first concave; and a first conductive region formed in the first concave and including a first doping region and a second doping region. Wherein the first doping region is formed based on the curved or depressed shape opening along the vertical direction of the sidewall of the semiconductor substrate.

According to one aspect of the invention, a top surface of the second doping region is flat or planar.

According to one aspect of the invention, he curved shape or depressed shape is a sigma-shaped (Σ) undercut.

According to one aspect of the invention, the transistor structure further includes a metal plug contacting a top surface and a most lateral sidewall of the second doping region, wherein the second doping region is a heavily doped region.

According to one aspect of the invention, the curved or depressed shape opening includes a plurality of non-vertical semiconductor segmental walls, and the first doping region is selectively grown based on the plurality of non-vertical semiconductor segmental walls.

According to one aspect of the invention, the transistor structure further includes a first isolation region in the first concave, and the first conductive region is above the first isolation region.

According to one aspect of the invention, the curved or depressed shape opening is under the first gate region.

Another object of the present disclosure is to provide a transistor structure, wherein the transistor structure includes a semiconductor substrate with an OSS, a first transistor and a second transistor. The first transistor includes a first gate region over the OOS; a first concave formed in the semiconductor substrate and below the OSS; a first curved or depress undercut formed in the semiconductor substrate, below the first gate region and communicating with the first concave; and a first conductive region with a first doping region and a second doping region. Wherein at least portion of the first doping region is within the first curved or depress undercut. The second transistor includes a second gate region over the OSS; a second concave formed in the semiconductor substrate and below the OSS; a second curved or depress undercut formed in the semiconductor substrate, below the second gate region and communicating with the second concave; and a second conductive region with a third doping region and a fourth doping region. Wherein at least portion of the third doping region is formed within the second curved or depress undercut.

According to one aspect of the invention, the transistor structure further includes a first metal plug and a second metal plug. Wherein, the first metal plug contacts a top surface and a most lateral sidewall of the second doping region; the second doping region is a heavily doped region; the second metal plug contacts a top surface and a most lateral sidewall of the fourth doping region, and the fourth doping region is a heavily doped region.

According to one aspect of the invention, the transistor structure further includes a first isolation region and a second isolation region. Wherein the first isolation region is in the first concave, the first conductive region is above the first isolation region; the second isolation region is in the first concave, and the second conductive region is above the second isolation region.

According to one aspect of the invention, a top surface of the second doping region is flat or planar, and a top surface of the fourth doping regions is flat or planar.

According to one aspect of the invention, the first curved or depressed undercut includes a plurality of non-vertical semiconductor segmental walls, and the first doping region is selectively grown based on the plurality of non-vertical semiconductor segmental walls; wherein the second curved or depressed undercut includes another plurality of non-vertical semiconductor segmental walls, and third doping region is selectively grown based on the another plurality of non-vertical semiconductor segmental walls.

According to one aspect of the invention, the doping concentration of the first doped region is different from the concentration of third doping region.

According to one aspect of the invention, the doping concentration of the second doped region is the same or substantially the same as the concentration of fourth doping region.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings:

FIG. 1A is a diagram illustrating a circuit diagram of a DRAM chip according to the prior art;

FIG. 1B is a cross sectional view illustrating a traditional CMOS structure:

FIG. 1C is a diagram illustrating the parasitic Metal-Gated-Diode formed in the Gate-to-Source/Drain regions of the MOSFET and the GIDL issue in MOSFET according to the prior art;

FIG. 2A is a top view illustrating the processing structure after the pad-nitride layer is deposited and the STI is formed in the semiconductor substrate to define the active regions for the NMOS and PMOS transistors and form; and FIG. 2B is a cross-sectional view taken along the cut line (X-axis) as depicted in FIG. 2A;

FIG. 3A is a top view illustrating the processing structure after the gate length is defined; and FIG. 3B is a cross-section view taken along the cut line (X-axis) as depicted in FIG. 3A;

FIG. 3-1A is a top view illustrating the processing structure after the shallow trench for forming the channel region is formed: and FIG. 3-1B is a cross-sectional view taken along the cut line (X-axis) as depicted in FIG. 3-1A;

FIG. 3-2A is a top view illustrating the processing structure after the channel region is selectively formed; and FIG. 3-2B is a cross-section view taken along the cut line (X-axis) as depicted in FIG. 3-2A;

FIG. 3-3A is a top view illustrating the processing structure after the shallow trench with a rounded shape for forming the channel region is formed; and FIG. 3-3B is a cross-sectional view taken along the cut line (X-axis)

FIG. 3-4A is a top view illustrating the processing structure after the channel region is selectively formed in the shallow trench with the rounded shape; and FIG. 3-48 is a cross-sectional view taken along the cut line (X-axis) as depicted in FIG. 3-4A;

FIG. 4A is a top view illustrating the processing structure after the gate conductive region is formed; and FIG. 4B is a cross-sectional view taken along the cut line (X-axis) as depicted in FIG. 4A;

FIG. 5A is a top view illustrating the processing structure after the gate cap region is formed; and FIG. 5B is a cross-sectional view taken along the cut line (X-axis) as depicted in FIG. 5A;

FIG. 6A is a top view illustrating the processing structure after the pad nitride and the pad oxide outside the gate region are removed; and FIG. 6B is a cross-sectional view taken along the cut line (X-axis) as depicted in FIG. 6A;

FIG. 7A is a top view illustrating the processing structure after the spacers over the sidewalls of the gate region are formed; and FIG. 7B is a cross-sectional view taken along the cut line (X-axis) as depicted in FIG. 7A;

FIG. 8A is a top view illustrating the processing structure after the concaves outside the gate region are formed; and FIG. 8B is a cross-sectional view taken along the cut line (X-axis) as depicted in FIG. 8A;

FIG. 9A is a top view illustrating the processing structure after the localized isolation layers in the concaves are formed; and FIG. 9B is a cross-sectional view taken along the cut line (X-axis) as depicted in FIG. 9A;

FIG. 10A is a top view illustrating the processing structure after portion of the localized isolation layers in the concaves are removed to expose vertical semiconductor sidewalls; and FIG. 10B is a cross-sectional view taken along the cut line (X-axis) as depicted in FIG. 10A;

FIG. 11A is a top view illustrating the processing structure after the vertical semiconductor sidewalls are etched to define a plurality of sigma-shaped (ΣZ) undercuts; and FIG. 11B is a cross-sectional view taken along the cut line (X-axis) as depicted in FIG. 11A;

FIG. 11B-1 is a cross-sectional view illustrating the processing structure after the vertical semiconductor sidewalls are etched to define a plurality of curved or depressed shape openings, such as a plurality of sigma-shaped (Σ) undercuts, according to another embodiment of the present disclosure;

FIG. 12A is a top view illustrating the processing structure after the semiconductor regions laterally growing from exposed silicon sidewalls in the curved or depressed shape openings, such as sigma-shaped (Σ) undercuts; and FIG. 12B is a cross-sectional view taken along the cut line (X-axis) as depicted in FIG. 12A;

FIG. 12B-1 is a cross-sectional view illustrating the processing structure after the semiconductor regions laterally growing from exposed silicon sidewalls in the curved or depressed shape openings, such as sigma-shaped (Σ) undercuts, as depicted in FIG. 11B-1;

FIG. 12C is a cross-sectional view illustrating the processing structure after the semiconductor regions laterally growing from exposed silicon sidewalls in the concaves according to another embodiment of the present disclosure;

FIG. 12C-1 is a cross-sectional view illustrating the processing structure after the semiconductor regions laterally growing from exposed silicon sidewalls in the concaves according to yet another embodiment of the present disclosure;

FIG. 13A is a top view of a new CMOS structure according to one embodiment of the present invention, and FIG. 13B is a diagram illustrating a cross section of the new CMOS structure along the cutline (Y-axis) in FIG. 13A;

FIG. 14 is a diagram illustrating of a traditional CMOS structure with the n+ and p+ regions not fully isolated by insulators;

FIG. 15A is a top view of the new CMOS structure with a NMOS transistor and a PMOS transistor; FIG. 15B is a diagram illustrating a cross section of the new CMOS structure along the horizontal dash cutline in FIG. 15A; and

FIG. 16 is a diagram illustrating the possible Latch-up path from the n+/p junction through the p-well/n-well junction to the n/p+ junction structure of a transitional CMOS structure.

### DETAILED DESCRIPTION OF THE DISCLOSURE

The present disclosure provides a transistor structure and the processing method thereof. The above and other aspects of the disclosure will become better understood by the following detailed description of the preferred but non-limiting embodiment(s). The following description is made with reference to the accompanying drawings:

Several embodiments of the present disclosure are disclosed below with reference to accompanying drawings. However, the structure and contents disclosed in the embodiments are for exemplary and explanatory purposes only, and the scope of protection of the present disclosure is not limited to the embodiments. It should be noted that the present disclosure does not illustrate all possible embodiments, and anyone skilled in the technology field of the disclosure will be able to make suitable modifications or changes based on the specification disclosed below to meet actual needs without breaching the spirit of the disclosure. The present disclosure is applicable to other implementations not disclosed in the specification.

This invention discloses a transistor and CMOSFET structure, especially used in the peripheral circuit of DRAM chip and in sense amplifiers of array core circuit of DRAM chip. The manufacturing method of the proposed NMOS and PMOS transistors is exemplarily illustrated as follows:
Step 10: Start.
Step 20: Based on the semiconductor substrate, define active regions for the NMOS and PMOS transistors and form deep shallow trench isolation (STI) structures.
Step 30: Form the gate structure above the original semiconductor surface of the semiconductor substrate.
Step 40: Form spacers covering the gate structure, and form concaves in the semiconductor substrate.
Step 50: Form localized isolation layers in the concaves.
Step 60: Expose sidewalls of silicon in the concaves, and Grow semiconductor regions laterally from exposed silicon sidewalls in the concaves to form the source region and drain region of the NMOS and PMOS transistors.

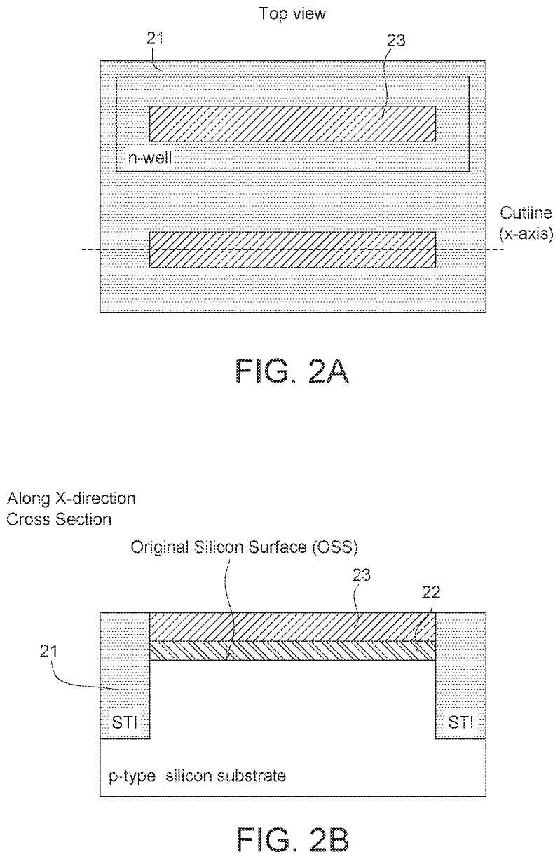

Please refer to FIG. 2A and FIG. 2B, Step 20 could include:
Step 202: A pad-oxide layer 22 is formed and a pad-nitride layer 23 is deposited.
Step 204: Use patterned photo-resistance (PR) to define the active regions of the NMOS and PMOS transistor, and remove parts of silicon material in the semiconductor substrate outside those active region patterns to create temporary trenches.
Step 206: Deposit oxide layer in the created temporary trenches, then etch back and planarize the oxide layer to form Shallow Trench Isolation (STI) 21, wherein the top surface of the STI 21 is aligned with the top surface of the pad-nitride layer 23, as shown in FIG. 2B which is the cross section view along the x-axis cutline in FIG. 2A.

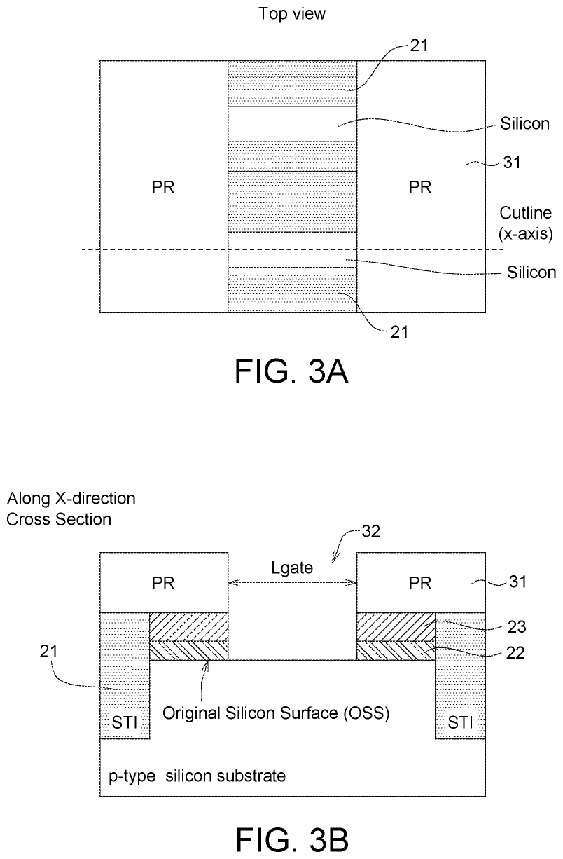

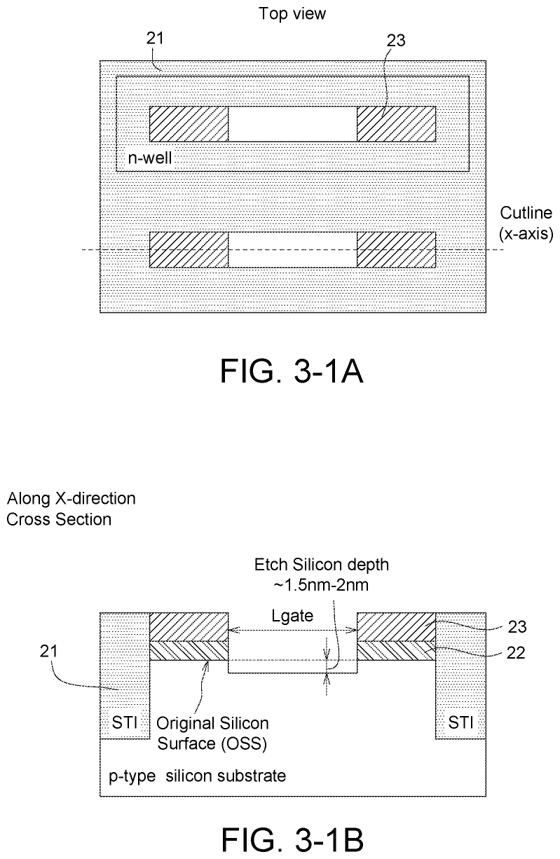

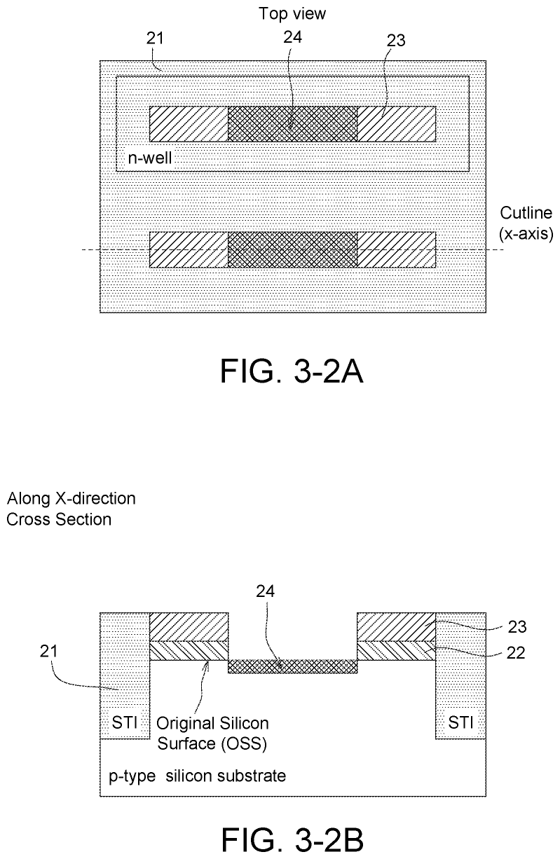

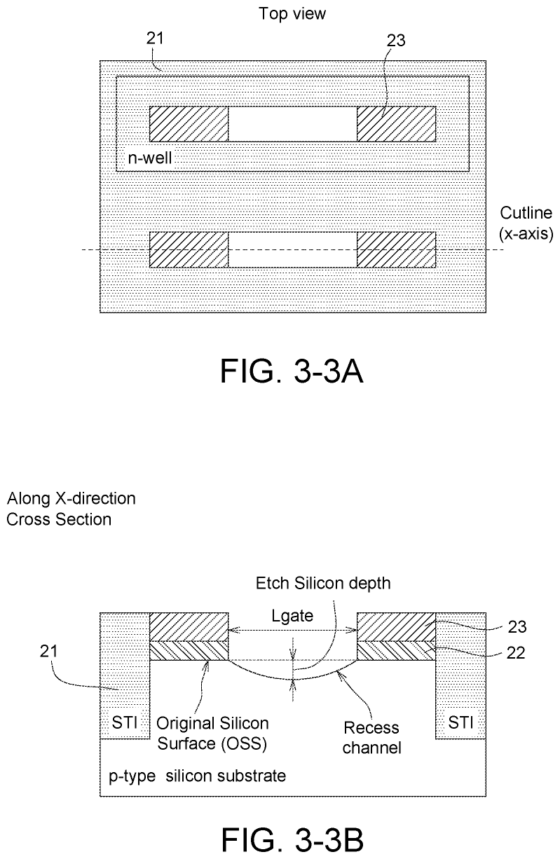

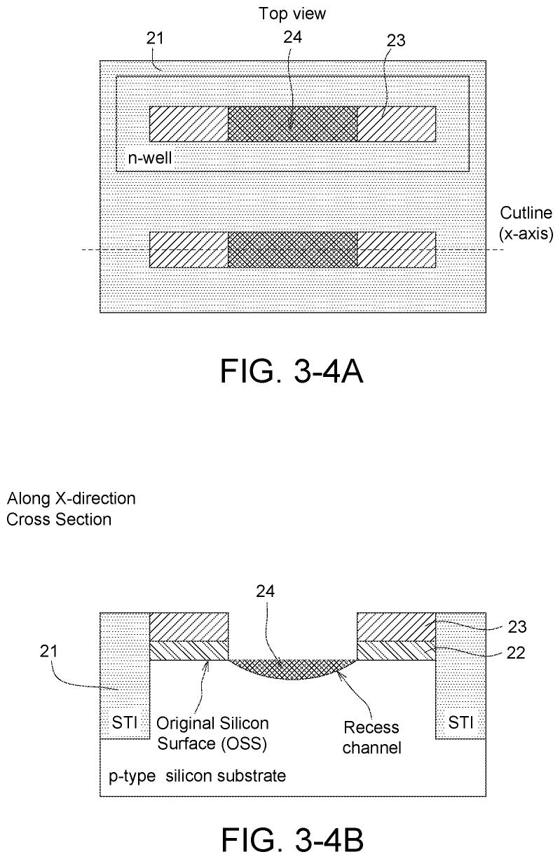

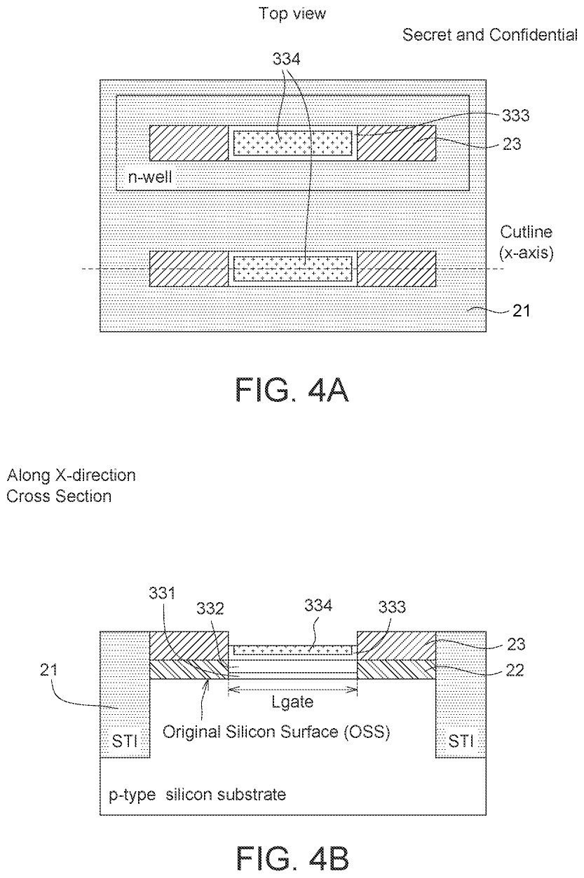

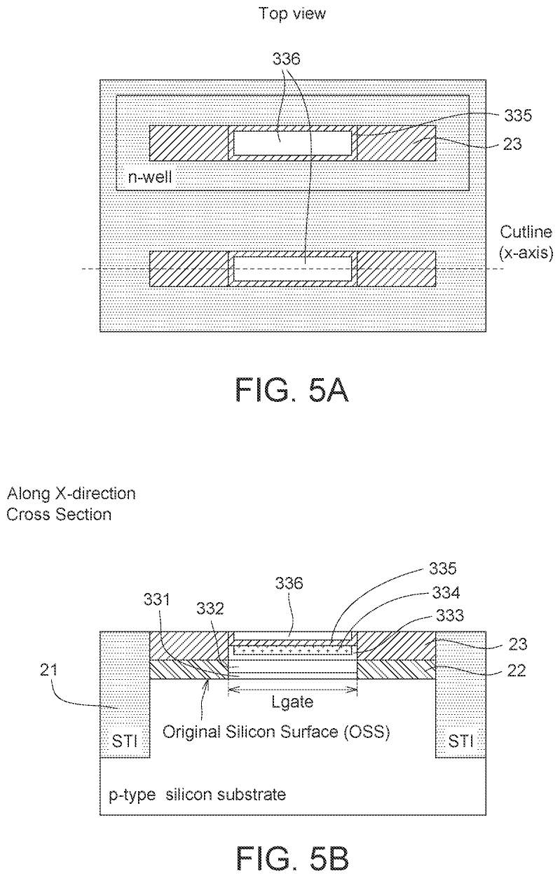

Please refer to FIG. 3 to FIG. 5, Step 30 of forming the gate structure could include:
Step 302: Use another patterned photo-resistance (PR) 31 to define the gate length (Lgate) of the gate regions for the NMOS and PMOS transistors, and then portion of the pad-oxide layer 302 and the pad-nitride layer 304 not covered by the PR are removed to form the gate accommodating trench 32, as shown in FIG. 3A and FIG. 3B, wherein FIG. 3B which is the cross section view along the x-axis cutline in FIG. 3A.
Step 304: subsequently form the gate dielectric layer 331 (such as thermal oxide or Hi-K material), gate conductive layer 332 which may including highly doped polysilicon (N+ polysilicon for MOS and P+ polysilicon for MOS), Ti/TiN layer 333, and Tungsten layer 334 in the gate accommodating trench 32, as shown in FIG. 4A and FIG. 4B, wherein FIG. 4B which is the cross section view along the x-axis cutline in FIG. 4A.
Step 306: Form a nitride cap layer 335 and an oxide cap 336 over the Tungsten layer 334 to complete the gate regions or gate structures of the NMOS and PMOS transistors, as shown in FIG. 5A and FIG. 5B, wherein FIG. 5B which is the cross section view along the x-axis cutline in FIG. 5A.

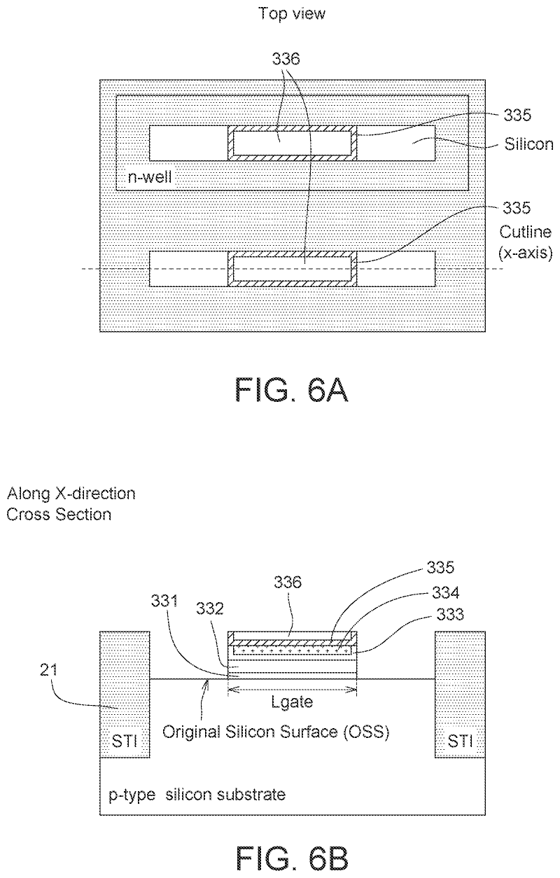

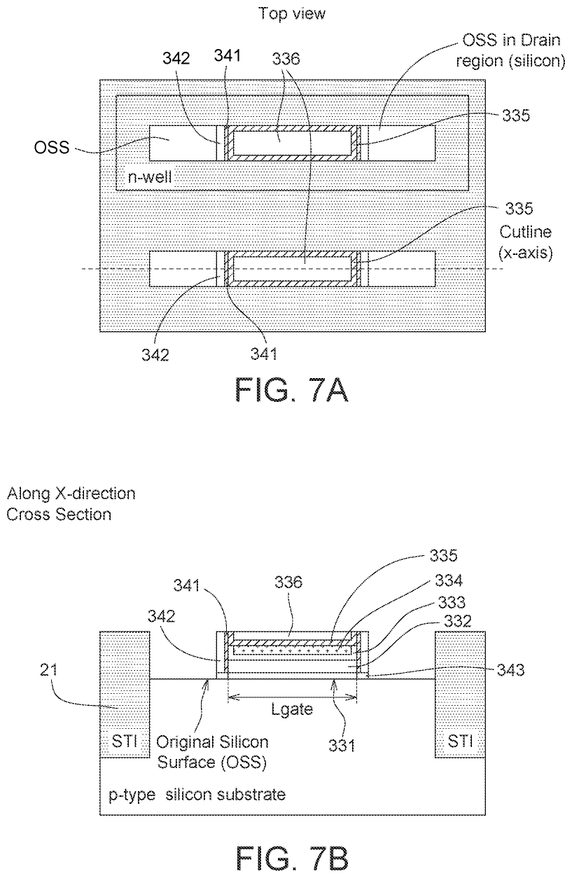

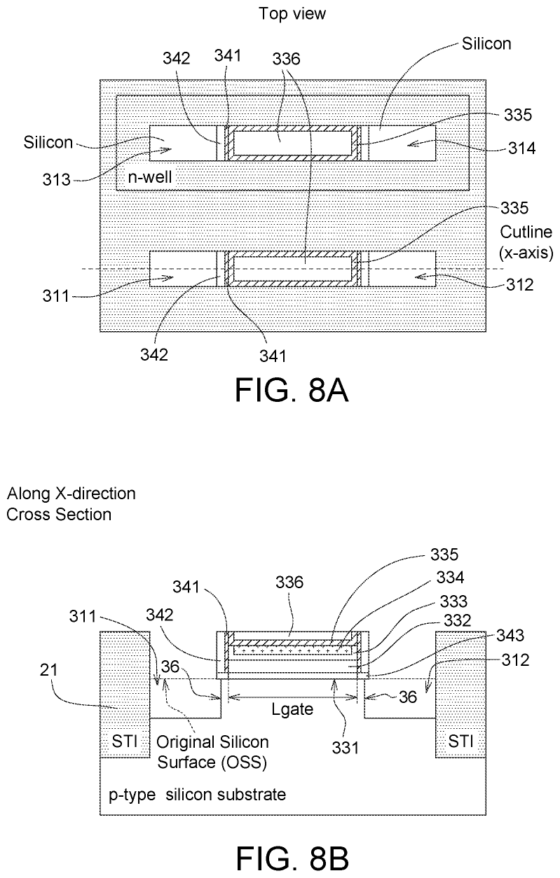

Then please refer to FIGS. 6-8, Step 40 could include:
Step 402: remove the pad-oxide layer 22 and the pad-nitride layer 23 between the STI layer 21 and the aforesaid gate regions to reveal the OSS of the semiconductor substrate, as shown in FIG. 6A and FIG. 6B, wherein FIG. 6B which is the cross section view along the x-axis cutline in FIG. 6A.
Step 404: form the spacer layer on the sides of the aforesaid gate regions, wherein the spacer layer may include a thin oxide sublayer 343 thermally grown on the OSS of the semiconductor substrate, a thin nitride sublayer 341 and a thin oxide sublayer 342 over thin oxide sublayer 343, as shown in FIG. 7A and FIG. 7B, wherein FIG. 78 which is the cross section view along the x-axis cutline in FIG. 7A.
Step 406: Etch portion of the semiconductor substrate to form concaves 311-314 in the semiconductor substrate, as shown in FIG. 8A and FIG. 8B, wherein FIG. 8B which is the cross section view along the x-axis cutline in FIG. 8A. Each concave 311-314 includes an exposed vertical side-surface 36 with (110) orientation right under the spacer layer in step 404, when the semiconductor substrate is a silicon substrate.

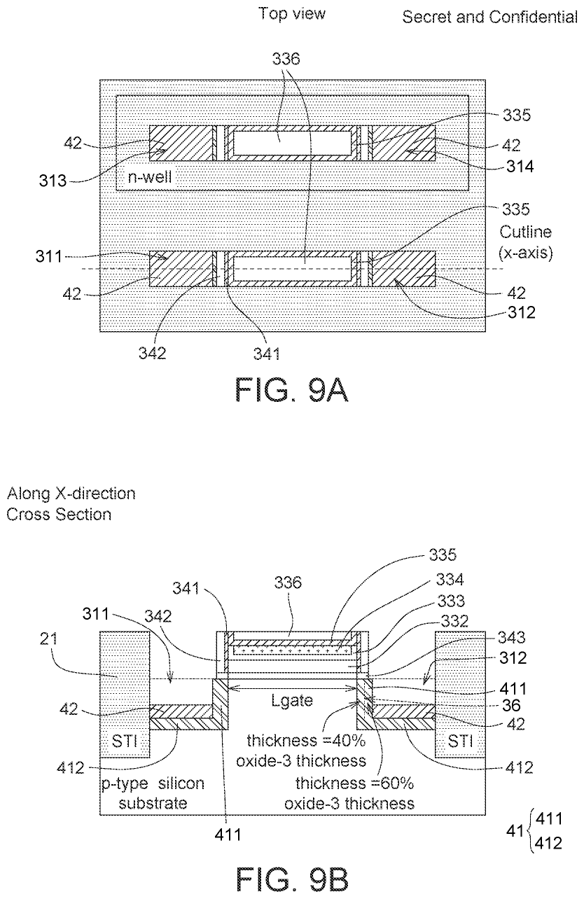

please refer to FIG. 9A and FIG. 9B, Step 50 could include: thermally grow an oxide-3 layer 41 which includes a vertical oxide-3V layer 411 covering the sidewalls of the aforesaid concaves 311-314 and a horizontal oxide-3B layer 412 covering the bottoms of the aforesaid concaves 311-314 in step 406. Afterward, deposit Nitride-3 material with sufficient thickness to fully fill up the aforesaid concaves 311-314 and then use an etch back process to remove the unnecessary portion of the Nitride-3 material to leave only a suitable Nitride-3 layer 42 inside the aforesaid concaves 311-314, as shown in FIG. 9A and FIG. 9B, wherein FIG. 9B which is the cross section view along the x-axis cutline in FIG. 9A, It is mentioned that the Nitride-3 layer 42 could be replaced by any suitable insulation materials.

To be mentioned, the thickness of the Oxide-3V layer 411 and the Oxide-3B layer 412 drawn in FIG. 9B and following figures are only shown for illustration purpose, but it is very important to design this thermally grown oxide-3 layer 41 such that the thickness of Oxide-3V layer 411 be very accurately controlled under both precisely controlled thermal oxidation temperature, timing and growth rate. The thermal oxidation over a well-defined silicon surface should result in that 40% of the thickness in Oxide-3V layer 411 takes away portion of silicon substrate from the aforesaid exposed (110) vertical side-surface 36, and the remaining 60% of the thickness of Oxide-3V layer 411 be counted as an addition outside the aforesaid exposed (110) vertical side-surface 36 (such a distribution of 40% and 60% on Oxide-3V layer 411 is particularly drawn clearly in FIG. 9B). Since the thickness of Oxide-3V layer 411 is very accurately controlled based on the thermal oxidation process, the edge of the Oxide-3V layer 411 could be aligned with the edge of the gate region. Of course, depending on the etching condition and thermal oxide growth condition, in another embodiment, part of Oxide-3V layer 411 (such as less than 5˜10%) could be underneath the gate structure.

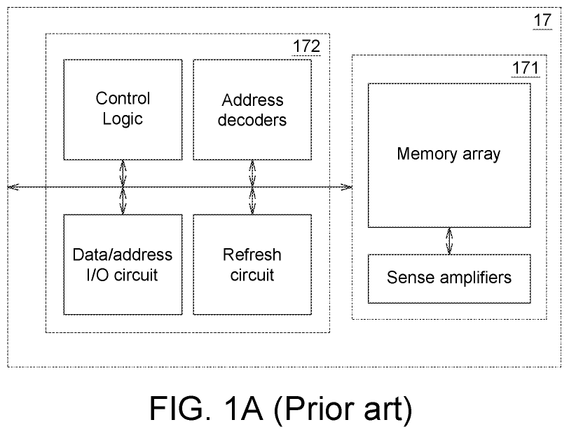

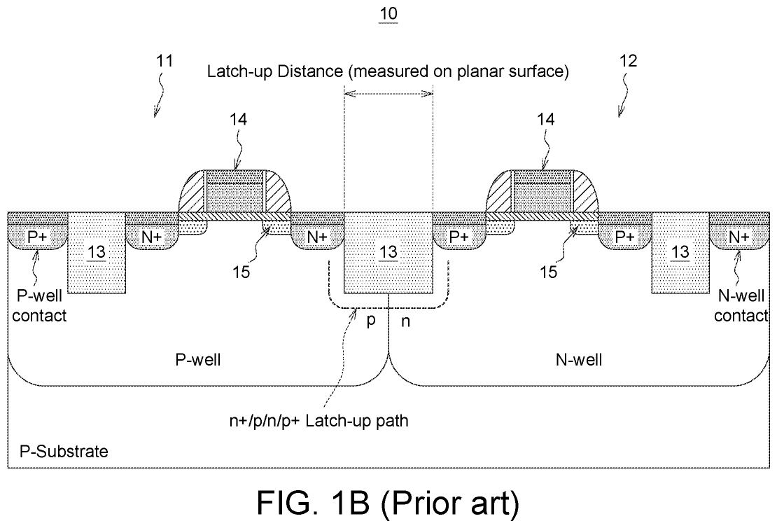

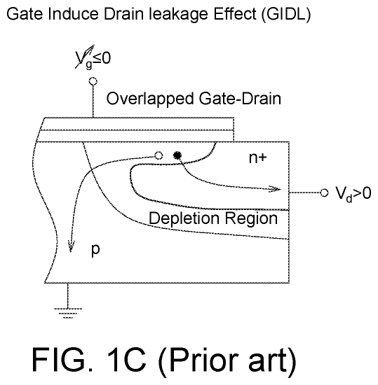

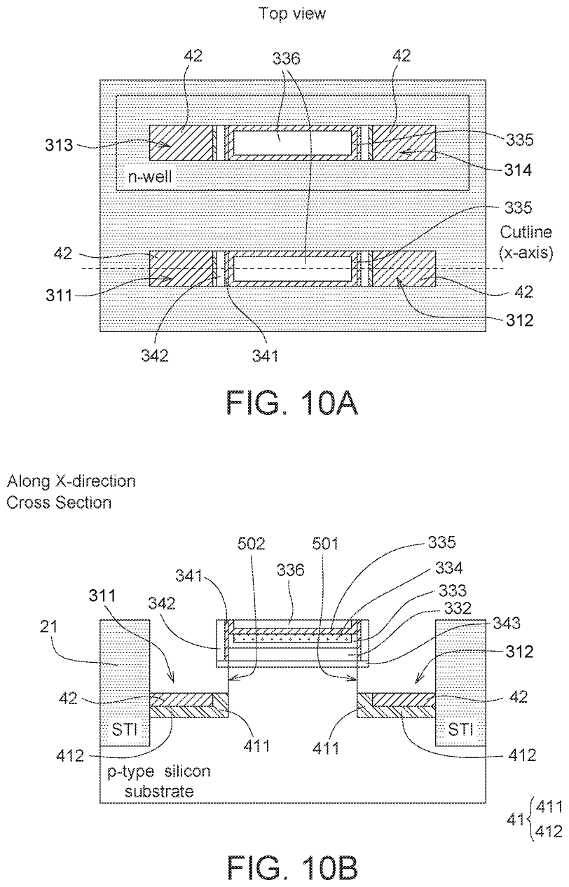

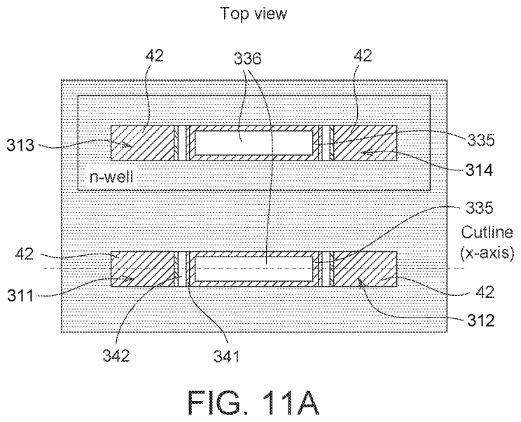

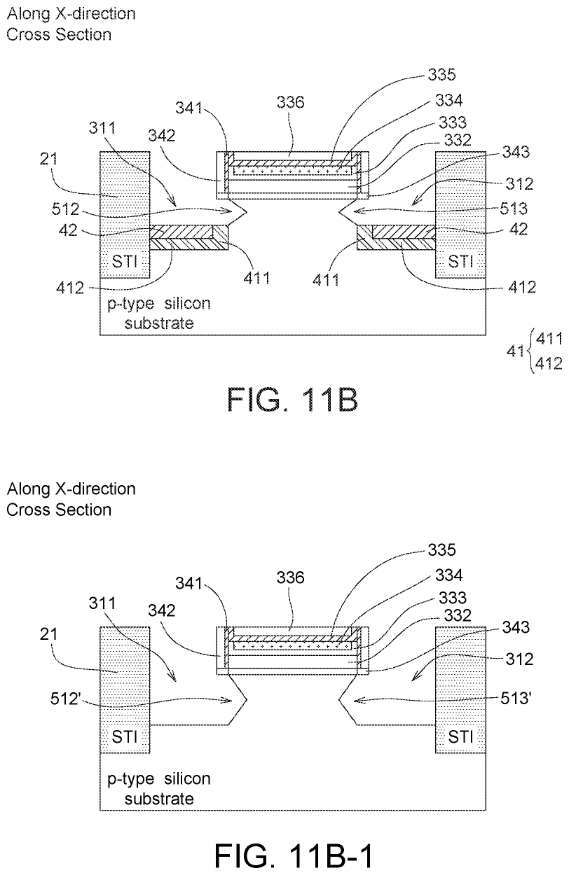

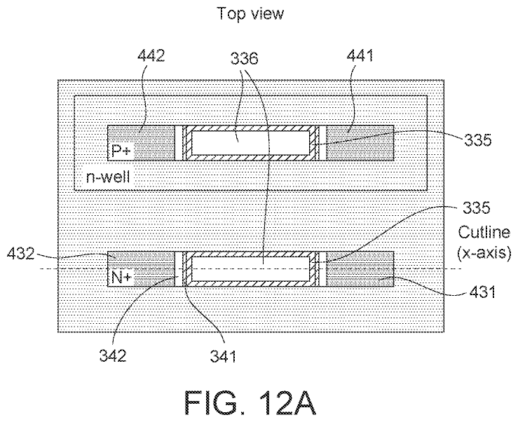

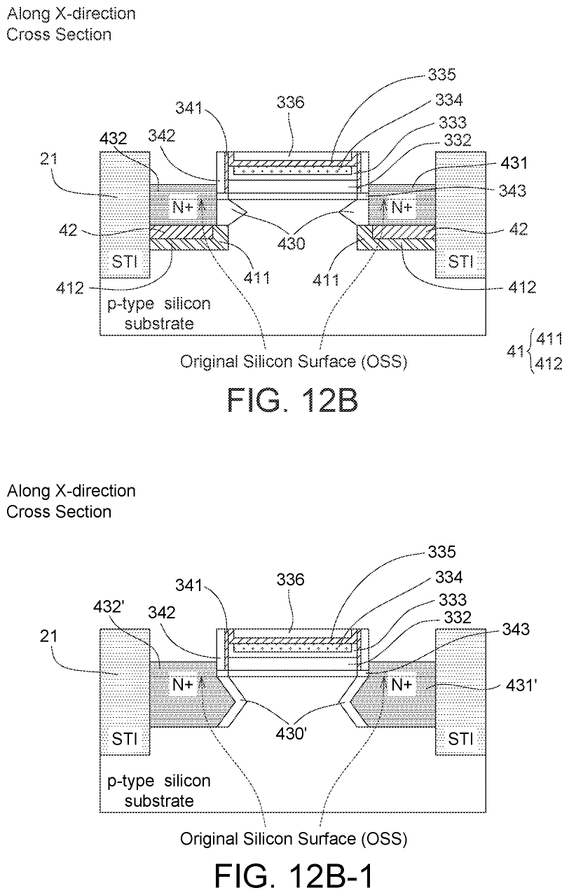

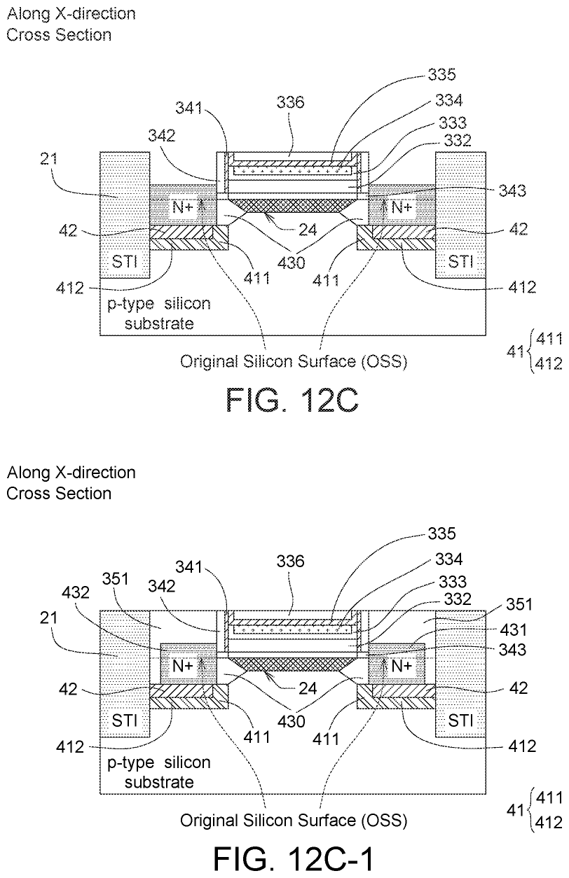

Please refer to FIG. 10A to FIG. 12B, Step 60 could include:
Step 602: portion of the Oxide-3V layer 411 above the Nitride-3 layer 42 are removed to expose vertical semiconductor sidewalls 501 and 502 in the concaves 311 and 312, as shown in FIG. 10A and FIG. 10B, again, those vertical semiconductor sidewalls 501 and 502 have (110) crystal orientation, when the semiconductor substrate is the silicon substrate. The remaining Oxide-3 layer 41 and the Nitride-3 layer 42 could be named as Localized Isolation into Silicon Substrate (“LISS”).
Step 604: the vertical semiconductor sidewalls 501 and 502 have (110) crystal orientation are etched to remove a portion of the channel regions and define curved or depressed shape openings along the vertical direction (such as, a plurality of circular arc shape openings or a plurality of sigma-shaped (Σ) undercuts 513 and 514) of the sidewalls or under the gate regions for the NMOS and PMOS transistors, for example each of the sigma-shaped (Σ) undercuts 513 and 514 respectively communicates with the corresponding concaves 311 and 312, and includes a plurality of non-vertical semiconductor segmental walls, as shown in FIG. 1A and FIG. 11B,
Step 606: grow the first semiconductor regions 430 laterally from the exposed non-vertical semiconductor sidewalls of the sigma-shaped (Σ) undercuts 513 and 514, respectively. Each of the first semiconductor regions 430 at least fills up the corresponding sigma-shaped (Σ) undercut 513 or 514, and includes a lightly doped region (or a Lightly Doped Drain, “LDD”), or include an undoped region plus a lightly doped region. The first semiconductor region 430 could be formed by selectively grown method, such as Selective Epitaxial Growth (SEG) technique or Atomic Layer Deposition (ALD) technique.
Step 608: grow the second semiconductor regions from those first semiconductor regions 430; each of the second semiconductor regions includes a highly doped region which could be formed by selectively grown method as well. Thus, the drain region of the NMOS transistor includes an N− LDD region and an N+ doped region 431; and the source region of the NMOS transistor includes another N− LDD region and an N+ doped region 432. Similarly, the drain region of the PMOS transistor includes a P− LDD region and a P+ doped region 441, and the source region of the PMOS transistor includes another P− LDD region and a P+ doped region 442, as shown in FIG. 12A and FIG. 12B, It is noted that, the top surface of the P+ doped region 441(442) or N+ doped region 431 (432) could be flat or planar, or substantially parallel with the OSS of the semiconductor substrate.

It is noted that, in one embodiment, each of the N− LDD region and the P− LDD region (such as, the first semiconductor region 430) formed by SEG technique or ALD technique has its horizontal boundary aligned (or substantially aligned) with the OSS of the semiconductor substrate, as shown in FIG. 12B. Thus, the alignment from the OSS of the semiconductor substrate can provide a more stable (plane) base for growing the second semiconductor regions (such as, the P+ doped regions 441 and 412 or the N+ doped regions 431 and 432) of the Source/Drain regions of the NMOS transistor and the PMOS transistor.

In some embodiments of the present disclosure, the first semiconductor regions 430 and the second semiconductor regions (such as, the P+ doped regions 441 and 412 or the N+ doped regions 431 and 432) can be formed by selective epitaxy silicon (Si), or silicon/germanium (SiGe). In the case of SiGe, it can provide the Source/Drain regions compressive strain to improve 10˜20% Ion for the NMOS transistor and the PMOS transistor.

Moreover, because no ion implantation and thermal annealing are required during the formation of the transistors. There is no need to use ion-implantation to form LDD region or the source/drain regions, there is no need to use thermal annealing process to reduce defects. Therefore, as no extra defects are generated once which were induced and hard to totally eliminate even by annealing process any unexpected leakage current sources should be significantly minimized.

In some embodiment, the source/drain regions of the NMOS and the PMOS transistors further include metal regions 351 formed over the N+ doped regions 431 and 432 of the source/drain region in the NMOS transistor as well as the P+ doped regions 441 and 442 of the source/drain in the PMOS transistor. In the present embodiment, as shown in FIG. 12C-1, the N+ doped regions 431 and 432 of the source/drain region in the NMOS transistor as well as the P+ doped regions 441 and 442 of the source/drain in the PMOS transistor do not fully fill the concave 311-314, and the metal regions 351 are formed on the N+ doped regions 431 and 432 and the P+ doped regions 441 and 442 to respectively full fill the concave 311-314 and surround the sidewalls of the N+ doped regions 431 and 432 and the P+ doped regions 441 and 442.

Furthermore, in some other embodiments of the present disclosure, the LISS (including the Oxide-3 layer 41 and the Nitride-3 layer 42) may be omitted. For example, a plurality of sigma-shaped (Σ) undercuts 513′ and 514′ under the gate regions for the NMOS and PMOS transistors can be formed by directly etch the exposed bottom surfaces and the vertical side-surface 36 of the concave 311-314 (as shown in FIG. 11B-1).

Then, the aforesaid the first semiconductor regions and the second semiconductor regions could be selectively grown. For example, the N− LDD regions 430′ of the drain/source region of the NMOS transistor and the P− LDD region (not shown) of the drain/source region of the PMOS transistor can be formed by selectively grown technology based on the non-vertical semiconductor segmental walls of the plurality of sigma-shaped (Σ) undercuts (e.g. the sigma-shaped (Σ) undercuts 513′ and 514′ of the NMOS transistor). The N+ doped region 431′ of the drain region and the N+ doped region 432′ of the source region are then can be formed by the selectively grown based on the N− LDD regions 430′ of the drain/source region in the NMOS transistor (as shown in FIG. 12B-1). The P− LDD regions (not shown) and the P+ doped regions (not shown) of the drain/source region in the PMOS transistor can be formed by similar method.

Meanwhile, in the example of FIG. 12B, each of the source and drain region of the transistors according to the present invention is isolated by insulation materials (the Nitride-3 layer 42 and the remaining oxide-3 layer 41) on the bottom structure, and isolated by STI layer 21 along three sidewalls, the junction leakage possibility can only happen to very small areas of the first semiconductor region 430 to channel region (right under the gate region of the transistor) and thus be significantly reduced.

In another embodiment, a channel region could be formed underneath and close to the Original Silicon Surface (OSS) of the semiconductor substrate (such as through ion-implantation) before the formation of the gate structure. However, besides the channel region formed by ion-implantation, a channel region according to the present invention could be formed by selective growth. For example, before forming the gate dielectric layer 331 in FIG. 4B, the revealed silicon surface could be etched to form a shallow trench with a depth of 1.5 nm˜3 nm, as shown in FIG. 3-1A and FIG. 3-1B. Then, a channel region 24 is selectively grown in the shallow trench, as shown in FIG. 3-2A and FIG. 3-2B.

Thereafter, the processes to form the gate region, the source region, and the drain region mentioned in FIG. 4A/FIG. 4B to FIG. 12A/FIG. 12B could be similarly applied to form another transistor structure shown in FIG. 12C.

Still in another embodiment, before forming the gate dielectric layer 331 in FIG. 4B, the revealed silicon surface could be etched to form a shallow trench with a rounded or curved shape, as shown in FIG. 3-3A and FIG. 3-3B. Then, a semiconductor channel region 24 is selectively grown along the sidewall of the shallow trench, as shown in FIG. 3-4A and FIG. 3-4B. Since the semiconductor channel region 24 is selectively grown along the sidewall of the shallow trench which is a curved or rounded shape, the channel length in this embodiment could be longer. Thereafter, the processes to form the gate region, the source region, and the drain region mentioned in FIG. 4A/FIG. 4B to FIG. 12A/FIG. 12B could be similarly applied to form another transistor.

In another embodiment (such FIG. 12C-1), the source (or drain) region could further comprise metal plug, such as TiN/Tungsten or other suitable metal materials, contacting the top surface and most lateral sidewall of the heavily doped region of source (or drain) region which is selectively grown. Thus, the source (or drain) region is a composite source (or drain) region. Thus, the external metal contact will be connected to the metal region of the composite source (or drain) region, and such Metal-to-Metal contact has much lower resistance than the traditional Silicon-to-Metal contact.

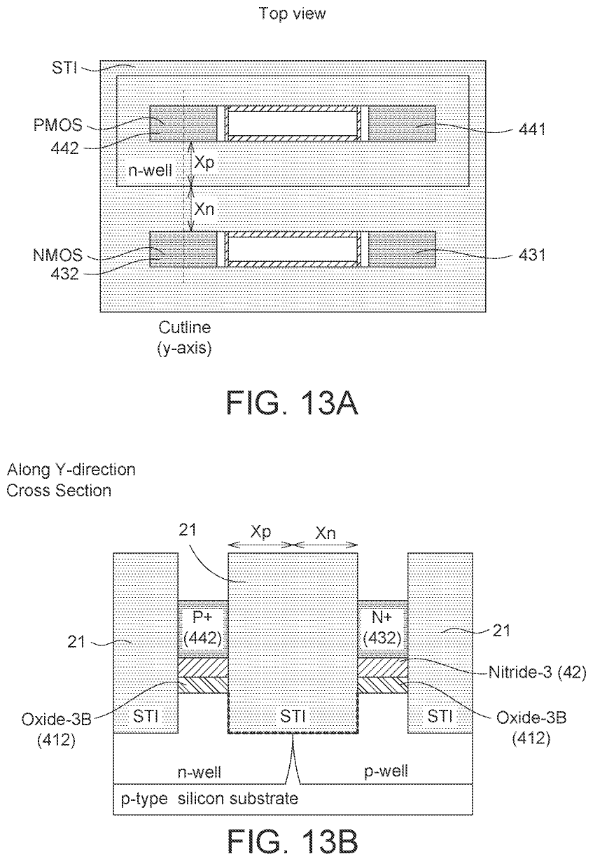

Furthermore, as shown in FIGS. 13A to 13B. FIG. 13A is a top view of the new CMOS structure according to one embodiment of the present invention, and FIG. 13B is a diagram illustrating a cross section of the new CMOS structure along the cutline (Y-axis) in FIG. 13A. The PMOS and NMOS transistors in FIGS. 13A to 13B. are vertically positioned side-by-side. In FIG. 13A, the four sides of the new CMOS structure is surrounded by the STI 21. Moreover, as shown in FIG. 13B, there exists the composite localized isolation (including the oxide-3 layer 412 and the nitride-3 payer 42) between the P+ source region 442 (or P+ drain region 441) of the PMOS and the n-type N-well, so is another composite localized isolation (including the oxide-3B layer 412 and the nitride-3 layer 42) between the N+ source region 432 (or N+ drain region 431) of the NMOS and the p-type P-well or substrate.

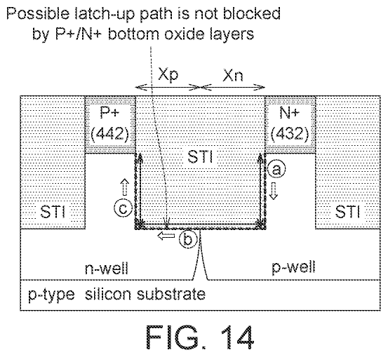

That is, each of drain region and source region of new CMOS structure is surrounded by the STI 21 on three sidewalls and by the composite localized isolation on the bottom wall. Thus, the possible latch-up path from the bottom of the P+ region of the PMOS to the bottom of the N+ region of the NMOS is fully blocked by localized isolations. Therefore, latch-up distance Xp+Xn (measured on planar surface) could be shrunk as small as possible without incurring serious latch-up issue. On the other hand, in the traditional CMOS structure the n+ and p+ regions are not fully isolated by insulators as shown in FIG. 1B or FIG. 14, the possible Latch-up path exists from the n+/p junction through the p-well/n-well junction to the n/p+ junction includes the length a, the length b, and the length c.

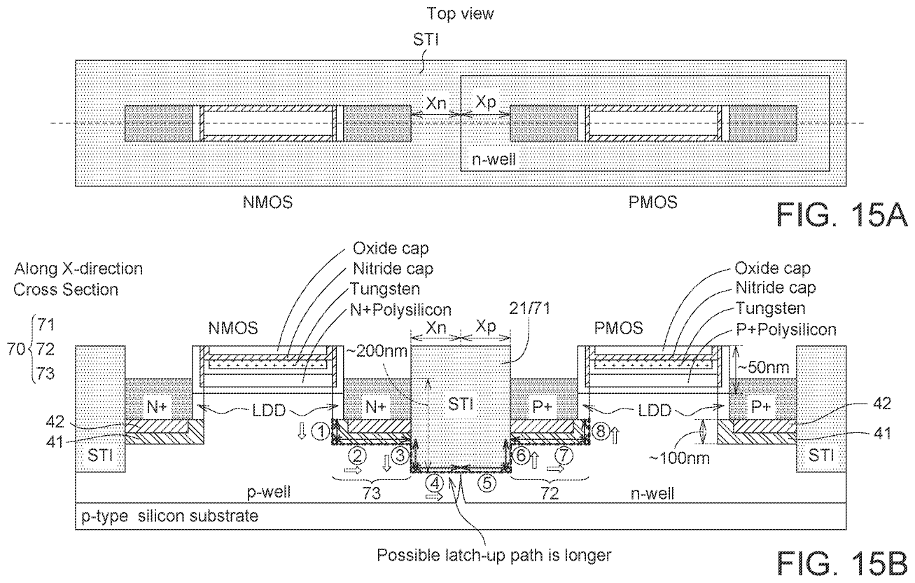

Furthermore, please refer to FIGS. 15A to 15B according to another embodiment of the present invention. FIG. 15A is a top view of the new CMOS structure with a NMOS transistor and a PMOS transistor, FIG. 15B is a diagram illustrating a cross section of the new CMOS structure along the horizontal dash cutline in FIG. 15A. The PMOS and NMOS transistors in FIGS. 15A to 15B are laterally positioned side-by-side. As shown in FIG. 15B, it could be simplified that there is a cross-shape LISS 70 between the PMOS transistor and NMOS transistor. The cross-shape LISS 70 includes a vertically extended isolation region 71 (such as the STI 21, the vertical depth under the OSS of the semiconductor substrate as shown in FIG. 15B would be around 150˜300 nm, such as 200 nm), a first horizontally extended isolation region 72 (the vertical depth would be around 50 nm-120 nm, such 100 nm) on the right hand side of the vertically extended isolation region 71, and a second horizontally extended isolation region 73 (the vertical length depth would be around 50 nm˜120 nm, such 100 nm) on the left hand side of the vertically extended isolation region 71. Each of the horizontally extended isolation regions could include the oxide-3 layer 41 and the nitride-3 layer 42. The vertical depth of the source/drain region of the PMOS/NMOS transistor is around 30˜50 nm, such as 40 nm. The vertical depth of the gate region of the PMOS/NMOS transistor is around 40˜60 nm, such as 50 nm shown in FIG. 15B.

In this embodiment, the first and second horizontally extended isolation regions 72/73 are not right underneath the gate structure or the channel of the transistor. The first horizontally extended isolation region 72 (right hand side of the vertically extended isolation region 71) contacts to a bottom of the source/drain region of the PMOS transistor, and the second horizontally extended isolation region 73 (left hand side of the vertically extended isolation region 71) contacts to a bottom of the source/drain region of the MMOS transistor. Therefore, the bottom sides of the source/drain regions in the PMOS and NMOS transistors are shield from the semiconductor substrate. Moreover, the first or second horizontally extended isolation region 72/73 may be composite isolation which could include two or more different isolation materials (such as the oxide-3 layer 41 and the Nitride-3 layer 42), or include two or more same isolation materials but each isolation material is formed by separate process.

As described before in the text and FIG. 1B, a drawback of conventional CMOS configuration/technology in contrast to pure-NMOS technology is that once a parasitic bipolar structure such as n+/p-sub/n-well/p+ junctions does exist and unfortunately some bad design cannot resist big current surges due to noises to trigger Latch-up to cause entire chip operation shutdown or permanent damages to chip functionality. The layout and process-rule for conventional CMOS always need to very large space to separate n+ source/drain regions of NMOS from the p+ source/drain regions of PMOS, called as Latch-up Distance (FIG. 1B) which consumes a lot of planar surfaces to inhibit any possibility of Latch-up. Moreover, if the source/drain n+/p and p+/n semiconductor junction area are too large, once the forward biasing accident is induced, the large surging current can be triggered to cause Latch-up.

The new CMOS structure in FIG. 15B results in a much longer path from the n+/p junction through the p-well (or p-substrate)/n-well junction to the n/p+ junction. As shown in FIG. 15B, according to the present invention, the possible Latch-up path from the LDD-n/p junction through the p-well/n-well junction to the n/LDD-p junction includes the length \textcircled{1}, the length \textcircled{2}(the length of the bottom wall of one horizontally extended isolation region), the length \textcircled{3}, the length \textcircled{4}, the length \textcircled{5}, the length \textcircled{6}, the length \textcircled{7} (the length of the bottom wall of another horizontally extended isolation region), and the length \textcircled{8} marked in FIG. 15B.

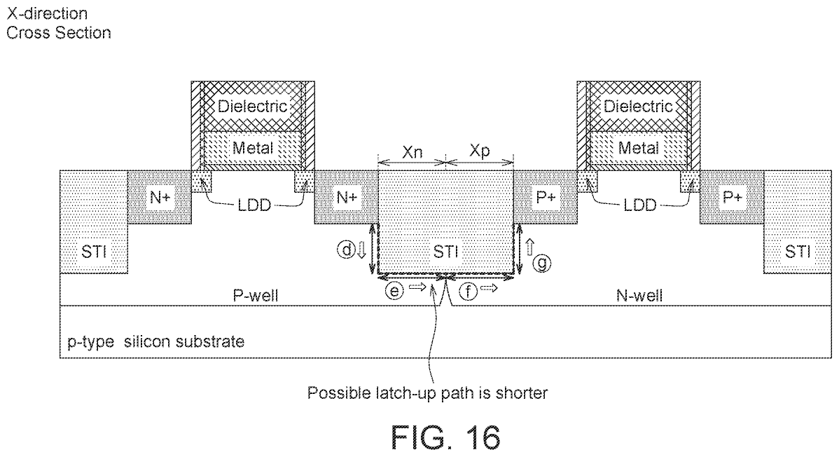

On the other hand, in traditional CMOS structure, the possible Latch-up path from the n+/p junction through the p-well/n-well junction to the n/p+ junction just includes the length d, the length e the length f, and the length g (as shown in FIG. 16). Such possible Latch-up path of FIG. 15B is longer than that in FIG. 16. Therefore, from device layout point of view, the reserved edge distance (Xₙ+Xₚ) between NMOS and PMOS in FIG. 15B according to the present invention could be smaller than that in FIG. 16. Moreover, in FIG. 15B, the potential Latch-up path begins from LDD-n/p junction to the n/LDD-p junction, rather than n+/p junction to the n/p+ junction in FIG. 16. Since the doping concentration in LDD-n or LDD-p region of FIG. 15B is lower than the doping concentration in n+ or p+ region of FIG. 16, the quantity of electrons or holes emitted from LDD-n or LDD-p region in FIG. 15B would be much lower than that emitted from n+ or p+ region in FIG. 16. Such lower emission of carriers will not only effectively decrease the possibility of induced Latch-up phenomenon, but also dramatically reduce the current even the Latch-up phenomenon is induced. Since both n+/p and p+/n junction areas are significantly reduced, even some abrupt forward-biasing of these junctions can reduce the abnormal current magnitude to deduct the chance of forming Latch-up in FIG. 15B.

Referring to FIG. 15B again, according to the present invention, the source or drain region of the PMOS is surrounded by the first horizontally extended isolation region 72 and the vertically extended isolation region 71, only the LDD region (the vertical length would be around 10-50 nm) of the source or drain region of the PMOS contacts to the semiconductor substrate to form a LDD-p/n junction, rather than p+/n junction. Similarly, the source or drain region of the MMOS is surrounded by the second horizontally extended isolation region 73 and the vertically extended isolation region 71, and only the LDD region (the vertical length would be around 40 nm) of the source or drain region of the NMOS contacts to the substrate to form a LDD-n/p junction, rather than p+/n junction. Therefore, the n+ regions of the NMOS and the p+ regions of the PMOS are shielded from the substrate or well region. Moreover, since the first or second horizontally extended isolation region 72/73 is composite isolation and thick enough, the parasitic Metal-Gated-Diode induced between the source (or drain) region and the silicon substrate could be minimized. It is expected that the planar Latch-up distance reserved for neighboring NMOS and PMOS transistors be significantly shortened such that the planar areas of the new CMOS can be largely reduced.

To sum up, since the source/drain regions of transistors of the CMOS structure are laterally outgrown from a curved or depressed shape opening along the vertical direction of sidewall of semiconductor substrate, the top surface of the source/drain regions could be flat or planar with good quality. Furthermore, the plane of LDD (Lightly Doped Drain) is outgrown horizontally from both transistor channel and substrate body with in-situ doping technique during the selective growth, there is no ion-implantation process which can only be formed from the top silicon downward into the source/drain regions and no thermal annealing process which can make junction boundaries hard to be defined and controlled. Unlike the conventional doped regions formed by ion-implantation process, such selectively grown semiconductor regions (such as undoped region, LDD region, and heavily doped region) are independent from the semiconductor substrate. The present invention could be applied to not only the planar transistor structure, but also applied to fin-shape transistor structure or transistor structure.

Moreover, in the present invention the SEG formation of LDD to heavily doped regions even including various non-silicon dopants such as Germanium or Carbon atoms to increase stresses to enhance channel mobility. The doping concentration profile is controllable or adjustable in the SEG/ALD formation of source/drain regions according to the present invention.

Those skilled in the art will readily observe that numerous modifications and alterations of the device and method may be made while retaining the teachings of the invention. Accordingly, the above disclosure should be construed as limited only by the metes and bounds of the appended claims. 31,

What is claimed is:

1. A transistor structure comprising:
a semiconductor substrate with an original semiconductor surface (OSS);
a first gate region;
a first concave formed in the semiconductor substrate and below the original semiconductor surface;
a curved or depressed shape opening formed along the vertical direction of a sidewall of the semiconductor substrate in the first concave; and
a first conductive region formed in the first concave and including a first doping region and a second doping region;
wherein the first doping region is formed based on the curved or depressed shape opening along the vertical direction of the sidewall of the semiconductor substrate.

2. The transistor structure according to claim 1, wherein a top surface of the second doping region is flat or planar.

3. The transistor structure according to claim 1, wherein the curved or depressed shape opening is a sigma-shaped (Σ) undercut.

4. The transistor structure according to claim 1, further comprising a metal plug contacting a top surface and a most lateral sidewall of the second doping region, wherein the second doping region is a heavily doped region.

5. The transistor structure according to claim 1, wherein the curved or depressed shape opening includes a plurality of non-vertical semiconductor segmental walls, and the first doping region is selectively grown based on the plurality of non-vertical semiconductor segmental walls.

6. The transistor structure according to claim 1, further comprising a first isolation region in the first concave, and the first conductive region is above the first isolation region.

7. The transistor structure according to claim 1, wherein the curved or depressed shape opening is under the first gate region.

8. A transistor structure comprising:
a semiconductor substrate with an OSS,
a first transistor comprising:
a first gate region over the OOS;
a first concave formed in the semiconductor substrate and below the OSS:
a first curved or depress undercut formed in the semiconductor substrate, below the first gate region and communicating with the first concave; and
a first conductive region with a first doping region and a second doping region; wherein at least portion of the first doping region is within the first curved or depress undercut; and
a second transistor comprising:
a second gate region over the OSS;
a second concave formed in the semiconductor substrate and below the OSS;
a second curved or depress undercut formed in the semiconductor substrate, below the second gate region and communicating with the second concave; and
a second conductive region with a third doping region and a fourth doping region; wherein at least portion of the third doping region is within the second curved or depress undercut.

9. The transistor structure according to claim 8, further comprising:
a first metal plug contacting a top surface and a most lateral sidewall of the second doping region, wherein the second doping region is a heavily doped region; and
a second metal plug contacting a top surface and a most lateral sidewall of the fourth doping region, wherein the fourth doping region is a heavily doped region.

10. The transistor structure according to claim 8, further comprising:
a first isolation region in the first concave, and the first conductive region is above the first isolation region; and
a second isolation region in the first concave, and the second conductive region is above the second isolation region.

11. The transistor structure according to claim 8, wherein a top surface of the second doping region is flat or planar, and a top surface of the fourth doping regions is flat or planar.

12. The transistor structure according to claim 8, wherein the first curved or depressed undercut includes a plurality of non-vertical semiconductor segmental walls, and the first doping region is selectively grown based on the plurality of non-vertical semiconductor segmental walls; wherein the second curved or depressed undercut includes another plurality of non-vertical semiconductor segmental walls, and third doping region is selectively grown based on the another plurality of non-vertical semiconductor segmental walls.

13. The transistor structure according to claim 8, wherein a doping concentration of the first doped region is different from that of third doping region.

14. The transistor structure according to claim 8, wherein a doping concentration of the second doped region is the same or substantially the same as that of fourth doping region.
